(19) United States
(12) Patent Application Publication
(10) Pub. No.: US 2025/0113564 A1
(43) Pub. Date: Apr. 3, 2025

(54) EPI HEIGHT REDUCTION FOR IMPROVED TRANSISTOR PERFORMANCE

(71) Applicant: Intel Corporation, Santa Clara, CA (US)

(72) Inventors: Leonard Guler, Hillsboro, OR (US); Charles H. Wallace, Portland, OR (US)

(73) Assignee: Intel Corporation, Santa Clara, CA (US)

(21) Appl. No.: 18/375,320

(22) Filed: Sep. 29, 2023

(51) Int. Cl. H01L 29/06; H01L 21/311; H01L 21/762; H01L 29/66; H01L 29/786

(52) U.S. Cl. CPC H10D 62/121; H01L 21/31116; H01L 21/76205; H10D 30/6755; H10D 62/115; H10D 64/017

(57) ABSTRACT

An integrated circuit (IC) device has a stack of nanoribbons between epitaxial source and drain structures with first and second dielectric sections separated by a dielectric layer and adjacent an epitaxial structure. A second dielectric layer may separate a third dielectric section. The dielectric layers may be conformally between the epitaxial structure and the dielectric sections. A height at a top of the epitaxial structure may be reduced, for example, to be very close to a height at a top of the stack of nanoribbons, e.g., within a pitch or thickness of the nanoribbons.

### BACKGROUND

As the complexity of integrated circuit (IC) devices continually increase, and the size of the transistors within these devices decrease, techniques for reducing the size of various transistor elements are needed. The size of these elements, including source and drain epitaxial structures, need to be lessened both to minimize the space occupied by a transistor, as well as capacitances between elements.

As transistors get smaller, capacitances between adjacent nodes and structures increase. In many transistors, gate-to-source and gate-to-drain capacitances increase significantly with gate height. Gate, source, and drain structures may all have substantially parallel conducting plates in close proximity. Techniques for minimizing or at least reducing a gate height include chemical-mechanical polishing (CMP) or planarization. Epitaxial source and drain structures extending up above tops of gate structures may be problematic, for example, due to the exposure of epitaxial structures to potential chemical contaminants and mechanical stressors.

New techniques are needed to reduce or minimize heights of epitaxial structures in IC transistors.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A, 1B, 1C, and 1D illustrate cross-sectional profile views of an integrated circuit (IC) device having transistor structures with low-profile epitaxial structures coupled to ends of nanoribbons, in accordance with some embodiments;

FIGS. 2A and 2B illustrate cross-sectional profile views of epitaxial structures, nanoribbons, and adjacent dielectric materials in an IC device, including various key heights, in accordance with some embodiments;

FIG. 3 is a flow chart of methods for forming an IC device with compact epitaxial structures, in accordance with some embodiments;

FIGS. 4A, 4B, 4C, 4D, 4E, 4F, 4G, 4H, and 4I illustrate cross-sectional profile views of an IC device having low-profile epitaxial structures coupled to nanoribbons, at various stages of manufacture, in accordance with some embodiments;

FIG. 5 illustrates a diagram of an example data server machine employing an IC device having compact epitaxial structures, in accordance with some embodiments; and

FIG. 6 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected.” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve the performance of integrated circuit (IC) devices with transistors having epitaxial structures. Many transistor structures have a substantially planar gate structure between and parallel to epitaxial source and drain structures. Particularly as device sizes shrink and device terminals are in increasingly close proximity, transistor performance is generally optimized by minimizing parallel heights of these gate and epitaxial source and drain structures. However, to ensure sufficient merging of epitaxial structures from ends of adjacent channel regions, epitaxial growth must not be overly constrained. While some processes may use a chemical-mechanical polishing (CMP) or planarization to reduce overly tall structure heights, CMP can be a messy operation, potentially introducing reliability issues and increasing process variation. While CMP may be satisfactory for reducing metal gate heights, rather than polishing epitaxial structures, improved methods are needed for reducing heights of source and drain structures.

The present disclosure describes a well-controlled technique for reducing heights of epitaxial structures. Epitaxial structures may be recessed relatively early in a fabrication process, e.g., by a contact-like etch, but prior to gate replacement and contact formation operations. Epitaxial structures may be covered in dielectric material before and after some etches (before contacting), but epitaxial structures may be protected from the dielectric material (and, e.g., oxidation) by one or more conformal liner layers.

Transistor structures with low-profile or compact epitaxial source and drain structures are described. Epitaxial structures may have heights nearly as low as a height of a highest nanoribbon in a stack of nanoribbons, e.g., within a nanoribbon pitch or thickness. Protective layers may be adjacent epitaxial structures.

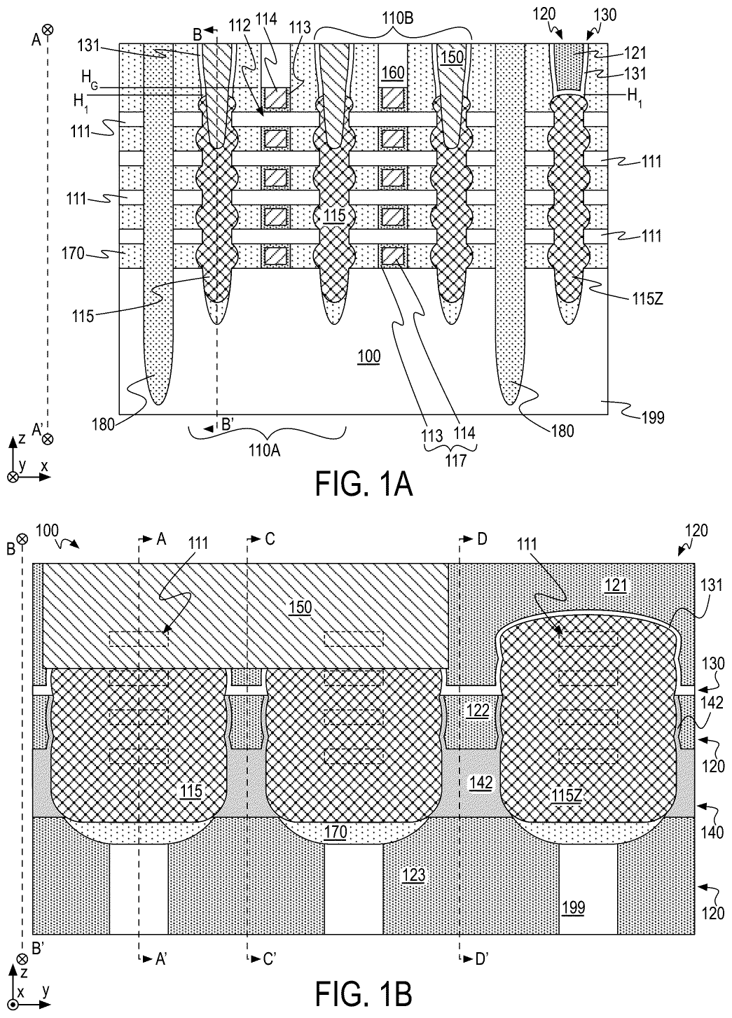

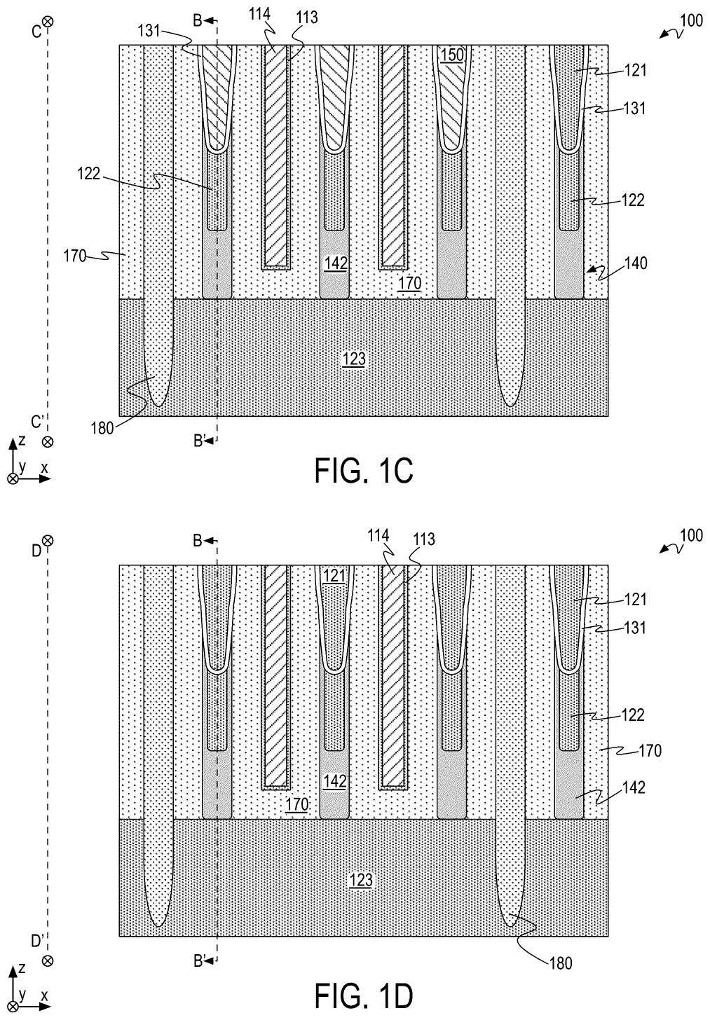

FIGS. 1A, 1B, 1C, and 1D illustrate cross-sectional profile views of an IC device 100 having transistor structures 110 with low-profile epitaxial structures 115 coupled to ends of nanoribbons 111, in accordance with some embodiments. FIGS. 1A, 1C, and 1D show profiles of transistor structures 110 at longitudinal cross-sections of nanoribbons 111. FIG. 1B shows transistor structures 110 at transverse cross-sections of nanoribbons 111. Cross-section lines A-A′ and B-B′ in FIGS. 1A and 1B indicate the relative perspectives of the x-z and y-z viewing planes of FIGS. 1A and 1B, respectively. Cross-section lines C-C′ and D-D′ in FIG. 1B likewise indicate the relative depths of the x-z viewing planes of FIGS. 1C and 1D, parallel to the plane of FIG. 1A.

FIG. 1A shows an IC apparatus or device 100, which includes multiple transistor structures 110. Transistor structures 110 each include a group of nanoribbons 111 in a stack, each nanoribbon 111 vertically above and/or below other nanoribbons 111. FIG. 1A shows stacks of four nanoribbons 111, but stacks may include two, three, four, or more nanoribbons 111. Transistor structures 110 each include epitaxial structures 115 (e.g., source and drain structures or regions) coupled to a stack of nanoribbons 111. Epitaxial structures 115 are doped semiconductor regions, each on an end of a stack of nanoribbons 111 and in contact with a metallization structure 150 over epitaxial structure 115. One or more epitaxial structures 115, e.g., structure 115Z, are adjacent other epitaxial structures 115, but are not within transistor structures 110 and are not contacted by any metallization structure 150. Epitaxial structure 115Z is in contact with a layer 131 of a dielectric material 130 over epitaxial structure 115. Intervening layer 131 is between epitaxial structure 115Z and an upper region or section 121 of a dielectric material 120. Layer 131 is between upper section 121 and a spacer structure 170. In some embodiments, layer 131 is between metallization structures 150 and spacer structures 170. In some embodiments, some metallization structures 150 (e.g., interconnect structures 150) are over non-contacted epitaxial structures 115Z, but structures 115Z are not electrically coupled to said structures (e.g., interconnect structures 150), for example, due to one or more intervening layers 131. Such non-contacted epitaxial structures 115Z and not electrically coupled interconnect structures may provide process uniformity, and minimize process variation, by acting as dummy or fill structures to maintain certain feature densities.

Transistor structures 110 each include a gate structure 117. Channel regions 112 are within nanoribbons 111, adjacent gate structure 117. Gate structure 117 includes a gate dielectric 113 around a gate metal 114. Gate dielectric 113 and gate metal 114 are adjacent nanoribbons 111. Gate dielectric 113 is between gate metal 114 and nanoribbons 111. Epitaxial structures 115 contacted by metallization structures 150 all have a height H₁ (e.g., at a top of structures 115) substantially equal to the height H₁ of non-contacted epitaxial structure 115Z. In some embodiments, a top of gate structure 117 (e.g., where a top of gate structure 117 contacts isolation structure 160) has a height HG the over height H₁ of epitaxial structures 115.

Spacer structure 170 is between gate structure 117 and epitaxial structures 115. Spacer structure 170 is of an electrically insulating material (e.g., a low-permittivity (“low-K”) or other dielectric material) and provides electrical isolation between adjacent circuit structures, such as structures 115, 117. In many embodiments, spacer structure 170 includes nitrogen, for example, in a nitride (e.g., of silicon). Isolation structure 160 is also of an electrically insulating material (such as a low-K dielectric) and provides electrical isolation. Isolation structure 160 is over gate metal 114 and may be an inter-layer dielectric (ILD). Gate metal 114 may be contacted by a metallization structure to one side or another of isolation structure 160 (e.g., in the y dimensions). Isolation structure 180 is of an electrically insulating material and provides electrical isolation between adjacent transistor structures 110, for example, between adjacent nanoribbons 111.

IC device 100 includes a substrate 199. Components of device 100 may be described as being in or on substrate 199. Substrate 199 may include any suitable material or materials. Any suitable semiconductor or other material can be used. Substrate 199 may be any suitable substrate, such as an IC wafer, die, etc. Substrate 199 may include a semiconductor material that transistors can be formed out of and on, including a crystalline material, such as monocrystalline or polycrystalline silicon (Si), germanium (Ge), silicon germanium (SiGe), a III-V alloy material (e.g., gallium arsenide (GaAs)), a silicon carbide (SiC), a sapphire (Al₂O₃), or any combination thereof. In some embodiments, substrate 199 includes crystalline silicon and subsequent components are also silicon. Substrate 199 may be a silicon-on-insulator (SOI) substrate. One or more fins of semiconductor material may be included in or on substrate 199. The fin or fins may be of the same material as the substrate or formed, e.g., deposited, on the substrate. Substrate 199 may also include semiconductor materials, metals, dielectrics, dopants, and other materials commonly found in IC substrates.

Epitaxial structures 115 are doped semiconductor regions. In some embodiments, at least some of epitaxial structures 115 are typical source and drain structures or regions in transistor structures 110 and device 100. In many embodiments, epitaxial structures 115 include silicon and germanium (e.g., SiₓGe_{y}). Other semiconductor materials may be employed. In many embodiments, epitaxial structures 115 include one or more dopants, such as boron, phosphorous, etc. Other dopant materials may be used. Any suitable means of formation may be used. Structures 115 are referred to as epitaxial, but no particular structure is thereby implied. Epitaxial structures 115 are substantially crystalline. In at least some embodiments, epitaxial structures 115 are polycrystalline. For example, epitaxial structures 115 may include multiple substantially monocrystalline structures, including on each of nanoribbons 111 terminating at structure 115, merged together between nanoribbons 111.

Transistor structures 110 (e.g., structures 110A, 110B) may include two or more epitaxial structures 115. For example, structures 110A, 110B may be electrically coupled as parallel legs (e.g., with epitaxial source structures 115 tied together to a voltage source V_{SS}, with a shared epitaxial drain structure 115 therebetween, and with gate structures 117 tied together).

FIG. 1B illustrates epitaxial structures 115 between nanoribbons 111 and adjacent various sections 121, 122, 123 and layers 131, 142 of dielectric materials. Although nanoribbons 111 contact epitaxial structures 115 to either side of the viewing plane (e.g., in the x dimensions) and do not extend to the viewing plane, the outlines of nanoribbons 111 are shown with dashed lines for reference.

IC device 100 includes an upper section 121 of dielectric material 120 adjacent epitaxial structures 115. IC device 100 includes a middle region or section 122 of dielectric material 120 adjacent epitaxial structures 115, under and adjacent upper section 121 of dielectric material 120. Intervening layer 131 of dielectric material 130 is between sections 121, 122. In some embodiments, as shown in FIG. 1B, layer 131 is between upper section 121 and epitaxial structures 115. In some embodiments, as shown in FIG. 1B, layer 131 contacts epitaxial structures 115 and upper section 121 between upper section 121 and epitaxial structures 115. Horizontal portions of intervening layer 131 contacts all shown epitaxial structures 115. Vertical portions of intervening layer 131 contact sidewalls of epitaxial structures 115. Layer 131 is a conformal layer over uncontacted epitaxial structure 115Z, between epitaxial structure 115Z and upper section 121. Though not the same uncontacted epitaxial structure 115Z as in the viewing plane of FIG. 1A, these example uncontacted epitaxial structures 115Z may be similar, even identical.

IC device 100 includes lower layer 142 of a dielectric material 140. Lower layer 142 contacts epitaxial structures 115 between middle section 122 and epitaxial structures 115, e.g., a vertical portion of layer 142 on a sidewall of epitaxial structures 115. Horizontal portions of lower layer 142 are under and adjacent middle section 122, and layer 142 is between middle section 122 and a lower region or section 123 of dielectric material 120. Nanoribbons 111 may be of the material of substrate 199, and device 100 and substrate 199 may include fins of the material under nanoribbons 111. Lower section 123 may be trench isolation sections 123 between fins of substrate 199 or other structures. Spacer structure 170 may be between epitaxial structures 115 and trench isolation sections 123.

Dielectric material 120 is not electrically conductive, and dielectric material 120 advantageously electrically insulates adjacent structures, e.g., epitaxial structures 115, in device 100. Advantageously, dielectric material 120 is conveniently formed in bulk, e.g., in between spacer structures 170 and over and between epitaxial structures 115. In many embodiments, dielectric material 120 includes oxygen, for example, in an oxide (such as an oxide of silicon (e.g., silicon dioxide, SiO₂). In some such embodiments, sections 121, 122, 123 have compositions substantially the same as the compositions of other sections 121, 122, 123. For example, though measurement and analysis of the compositions of sections 121, 122, 123 may show some variance, in some embodiments, all three sections 121, 122, 123 have an atomic composition of at least twenty percent oxygen. In some embodiments, all three sections 121, 122, 123 have an atomic composition of at least twenty percent silicon.

Dielectric materials 130, 140 are electrically insulative materials, and dielectric materials 130, 140 advantageously do not electrically conduct or connect adjacent structures, e.g., epitaxial structures 115, in device 100. Advantageously, an etch selectivity exists between dielectric material 120 and dielectric materials 130, 140, which may aid in the formation (including recessing, etc.) of various structures, such epitaxial structures 115. In many embodiments, dielectric materials 130, 140 include nitrogen, for example, in a nitride. For example, dielectric material 130 (and layer 131) may have an atomic composition of at least twenty percent nitrogen. Dielectric material 140 (and layer 142) may have an atomic composition of at least twenty percent nitrogen. In some embodiments, dielectric materials 130, 140 are or include a nitride of silicon (e.g., Si_{y}Nₓ). In some such embodiments, dielectric material 130 (and layer 131) has an atomic composition of at least twenty percent silicon and at least twenty percent nitrogen. In some such embodiments, dielectric material 140 (and layer 142) has an atomic composition of at least twenty percent silicon and at least twenty percent nitrogen. In at least some embodiments, dielectric materials 130, 140 include no (or only minimal amounts of) oxygen, for example, having an atomic composition of less than fifteen percent oxygen. In some embodiments, layers 131, 142 (and materials 130, 140) have compositions substantially the same as the compositions of the others of layers 131, 142 (and materials 130, 140). In some embodiments, layer 131 and/or 142 (and material 130 and/or 140) have compositions substantially the same as the compositions of spacer structures 170.

Advantageously, dielectric materials 130, 140 are conveniently formed conformally, e.g., over and between epitaxial structures 115 and spacer structures 170. Dielectric materials 130, 140 may advantageously provide protection (e.g., chemically) for epitaxial structures 115 (for example, from dielectric material 120). In some embodiments, dielectric materials 130, 140 protect epitaxial structures 115 from dielectric material 120. In some such embodiments, dielectric materials 130, 140 protect epitaxial structures 115 from an oxidizing reaction during a formation of dielectric material 120 (e.g., at a curing or other elevated-temperature operation).

Multiple epitaxial structures 115 are in contact with metallization structure 150 over epitaxial structures 115. Although contacted epitaxial structures 115 may appear to have a shorter height than non-contacted epitaxial structure 115Z, all epitaxial structures 115 may have a similar height (e.g., a substantially equal height) at a top of epitaxial structures 115 (e.g., out of the viewing plane, to the side of metallization structure 150).

FIG. 1C shows a viewing plane C-C′ parallel to plane A-A′ of FIG. 1A, for example, deeper or behind (e.g., in the y dimension), between adjacent parallel stacks of nanoribbons 111 and associated epitaxial structures 115. Dielectric layers 142 and dielectric sections 122 are between spacer structures 170. Dielectric section 123 is under dielectric layers 142. Next to contacted epitaxial structures 115, intervening layer 131 is between metallization structure 150 and dielectric section 122. Next to non-contacted epitaxial structure 115Z, intervening layer 131 is between dielectric sections 121, 122. In some embodiments, as shown in FIG. 1C, gate dielectrics 113 and gate metals 114 continue between stacks of nanoribbons 111.

FIG. 1D illustrates a viewing plane D-D′ parallel to plane A-A′ and C-C′ of FIGS. 1A and 1C, for example, deeper or behind (e.g., in the y dimension), between adjacent parallel stacks of nanoribbons 111 and clear of metallization structure 150. Various dielectric materials 120, 130, 140 are between spacer structures 170, between epitaxial structures 115.

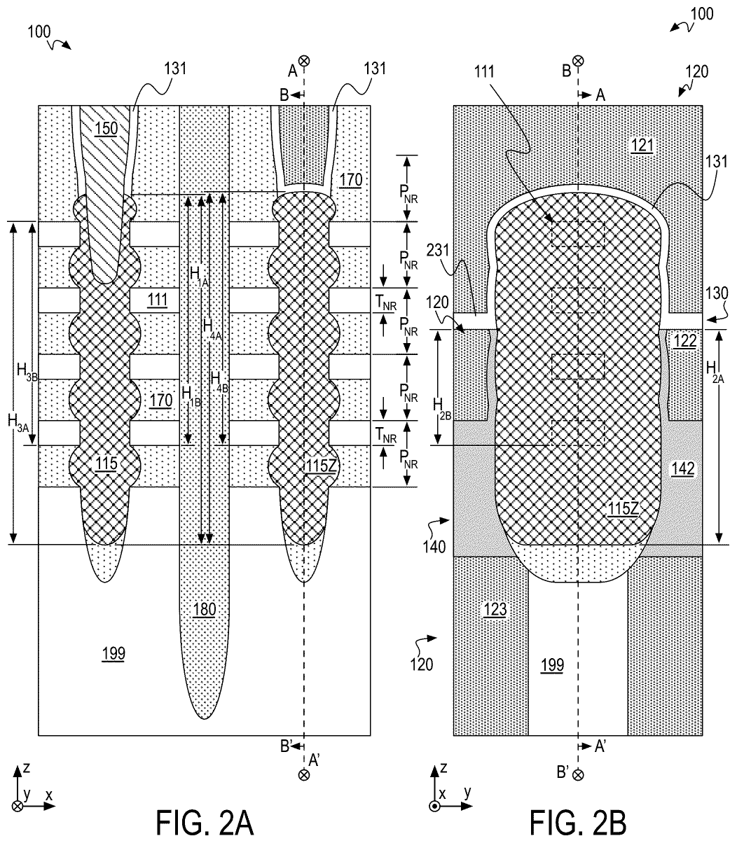

FIGS. 2A and 2B illustrate cross-sectional profile views of epitaxial structures 115, nanoribbons 111, and adjacent dielectric materials 120, 130, 140 in IC device 100, including various key heights H₁, H₂, H₃, H₄, in accordance with some embodiments. FIGS. 2A and 2B may show an embodiment of device 100 substantially as described at least at FIGS. 1A-1D. FIG. 2A shows a profile along a longitudinal section of nanoribbons 111. FIG. 2B shows an orthogonal profile along a transverse section of nanoribbons 111. FIGS. 2A and 2B are vertically aligned (e.g., at the same heights), and viewing planes A-A′ and B-B′ of FIGS. 2A and 2B intersect through non-contacted epitaxial structure 115Z. For example, the longitudinal section of nanoribbons 111 in FIG. 2A are aligned (e.g., at a same height) with the dashed transverse outlines of nanoribbons 111 in FIG. 2B. (The outlines of nanoribbons 111 are dashed in FIG. 2B to indicate that nanoribbons 111 do not extend to viewing plane B-B′ of FIG. 2B.) At least some heights are referenced with respect to multiple base or lower reference heights. For example, height H₁ to a top of epitaxial structure 115 is shown as both or either of height H_{1A} from a bottom of epitaxial structures 115 and as height HIB from a bottom of the lowest nanoribbon 111. Heights referenced from a bottom of the lowest nanoribbon 111 (e.g., heights H_{1B}, H_{2B}, H_{3B}, H_{4B}) may be more pertinent in some contexts, for example, for device heights, e.g., between or within or otherwise relating to the stack of nanoribbons 111.

A horizontal portion 231 of intervening layer 131 is between upper and middle dielectric sections 121, 122 and contacts epitaxial structures 115 (e.g., epitaxial structure 115Z) at (and above) a height H₂ (e.g., heights H_{2A}, H_{2B}). In some embodiments, the horizontal portion of intervening layer 131 between sections 121, 122 contacts epitaxial structures 115 in a middle third of an epitaxial structure 115. For example, a top of an epitaxial structure 115 is at height H_{1A} (or height H_{1B}), and layer 131 between sections 121, 122 is at height H_{2A} (or height H_{2B}, respectively), more than a third of height H_{2A} (or height H_{2B}, respectively), and less than two thirds of height H_{2A} (or height H_{2B}, respectively). Such a height H₂ may allow for sufficient recessing of epitaxial structure 115, while maintaining sufficient epitaxial structure 115, e.g., for contacting. Lower heights H₂ may correspond to more recessing and, e.g., reducing of top height H₁ of epitaxial structure 115. In some embodiments, heights H_{2A}. H_{2B} are within a nanoribbon thickness TNR of a middle nanoribbon 111 (in a stack with an odd number of nanoribbons 111) or between the middle pair of nanoribbons 111 (in a stack with an even number of nanoribbons 111). In some embodiments, heights H_{2A}, H_{2B} are within a nanoribbon thickness TNR of a third nanoribbon 111 in a stack of four nanoribbons 111 (the second-from-bottom nanoribbon 111). In some embodiments, heights H_{2A}. H_{2B} are between the lowest pair of nanoribbons 111 in the stack.

Such a height H₂ of intervening layer 131 may advantageously allow for a sufficient height of epitaxial structures 115 to be removed (e.g., by a recess etch) and/or exposed (e.g., by a contact etch) above layer 131, but to still retain a sufficient height of epitaxial structures 115. Lower heights H₂ (e.g., either of heights H_{2A} or H_{2B}) may correspond to more removal of epitaxial structures 115 and more clearance for subsequent processing. Greater heights H₂ (e.g., either of heights H_{2A} or H_{2B} may correspond to less removal of epitaxial structures 115, which may allow for more contact (e.g., along a greater contact height within epitaxial structure 115).

A top of epitaxial structures 115 may advantageously be sufficiently low to allow for subsequent processing (e.g., for polishing a gate metal down to a height still higher than a top of epitaxial structures 115) and sufficiently low to minimize (or at least have a sufficiently low) corresponding inter-terminal capacitance. In some embodiments, a height H₃ (e.g., height H_{3A} or H_{3B}) to a top surface of a top nanoribbon 111 of a stack of nanoribbons is within a vertical pitch P_{NR} to height H₁ at a top of epitaxial structure 115. (Vertical pitch P_{NR} is equal to a distance between corresponding surfaces of adjacent (e.g., consecutive) nanoribbons 111 in a stack of nanoribbons 111). In some embodiments, height H₃ to the top surface of the top nanoribbon 111 is within a thickness TNR of the top nanoribbon 111 to height H₁ at the top of epitaxial structure 115. In some embodiments, H₁ (e.g., height H_{1A} or H_{1B}) is substantially equal to height H₃ (e.g., height H_{3A} or H_{3B}), and a top of epitaxial structure 115 is approximately level with the top surface of the top nanoribbon 111.

Device 100 includes multiple metallization structures 150, each in contact with a corresponding one of multiple epitaxial structures 115. Another epitaxial structure 115 (e.g., epitaxial structure 115Z) adjacent the multiple contacted epitaxial structures 115 is not in contact with any metallization structures 150. In some embodiments, height H_{1A} (or height H_{1B}) at a top of a contacted epitaxial structure 115 is substantially equal to height H_{4A} (or height H_{4B}) at a top of non-contacted epitaxial structure 115Z. Such uniformity may advantageously minimize process variation for one or more subsequent fabrication operations, e.g., any operations following a recess etch of epitaxial structures 115, 115Z.

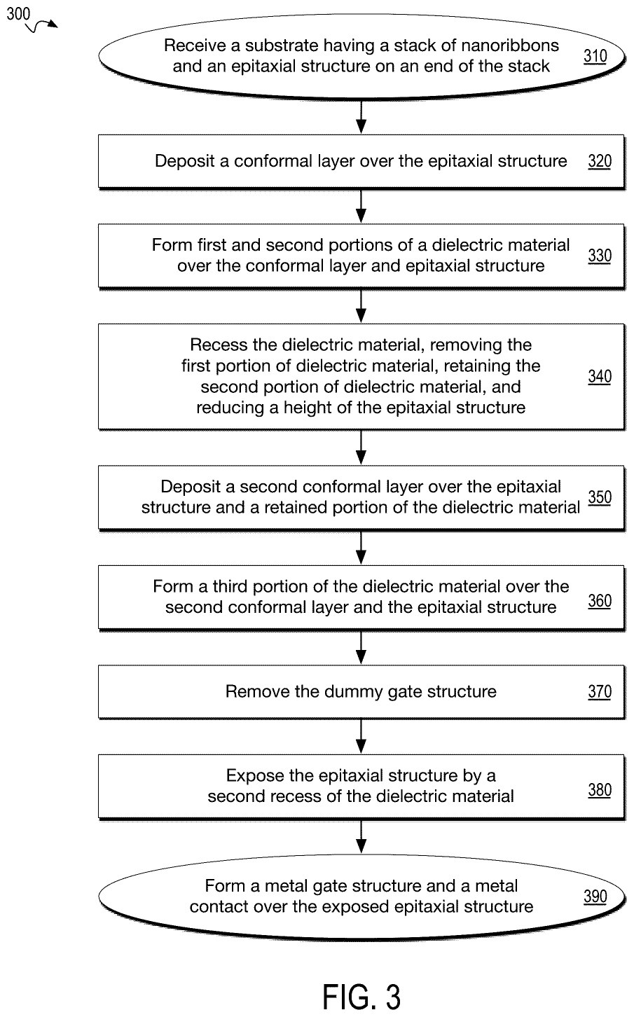

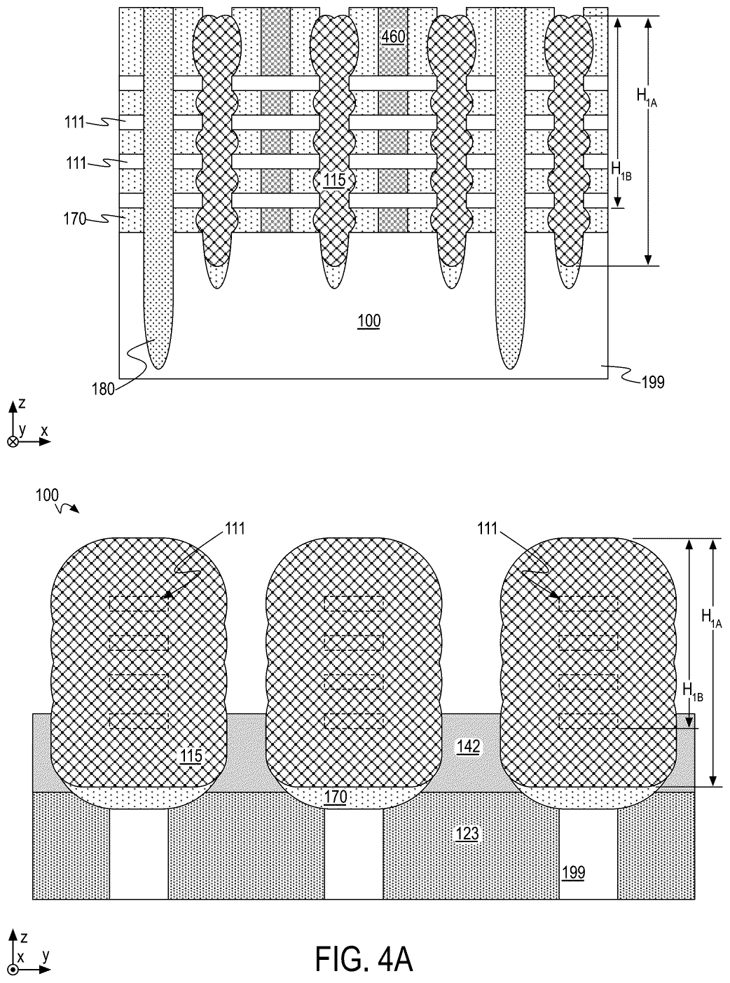

FIG. 3 is a flow chart of methods 300 for forming an IC device with compact epitaxial structures, in accordance with some embodiments. Methods 300 include operations 310-390. Some operations shown in FIG. 3 are optional. Additional operations may be included. FIG. 3 shows an example sequence, but the operations can be done in other orders as well, and some operations may be omitted. Some operations can also be performed multiple times before other operations are performed. Some operations may be included within other operations so that the number of operations illustrated FIG. 3 is not a limitation of the methods 300.

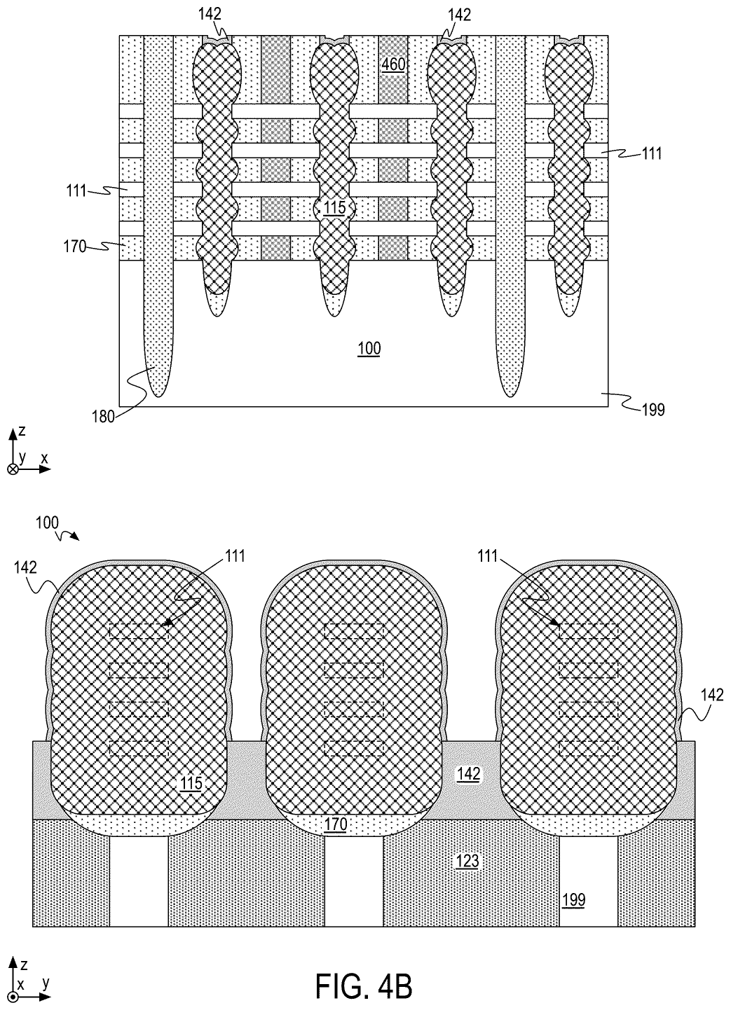

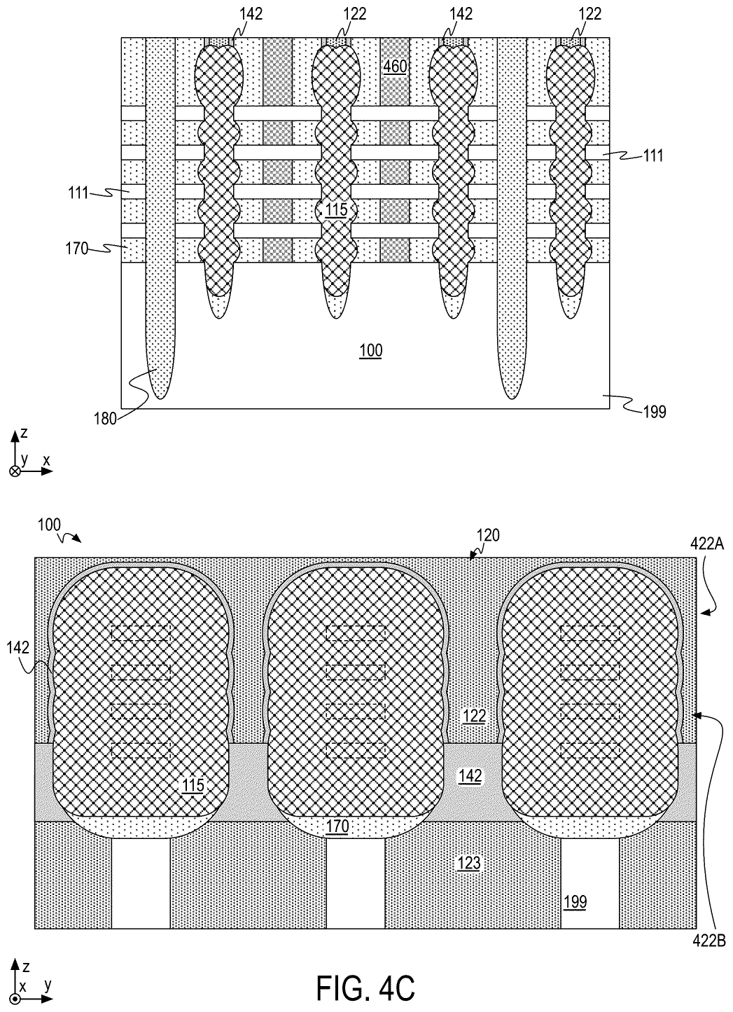

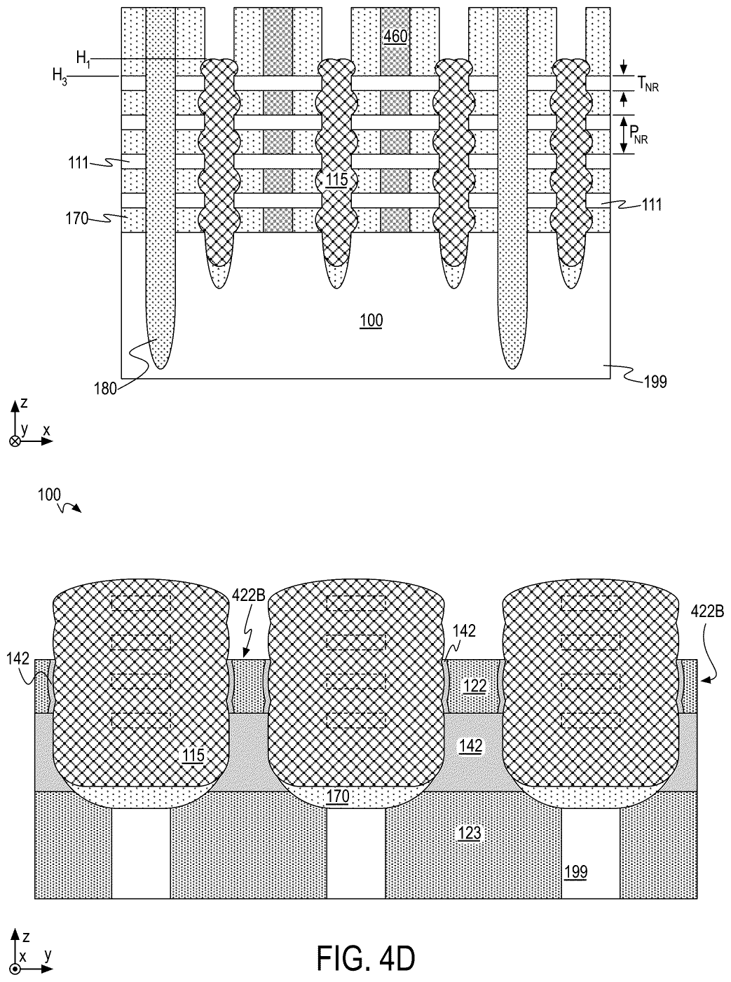

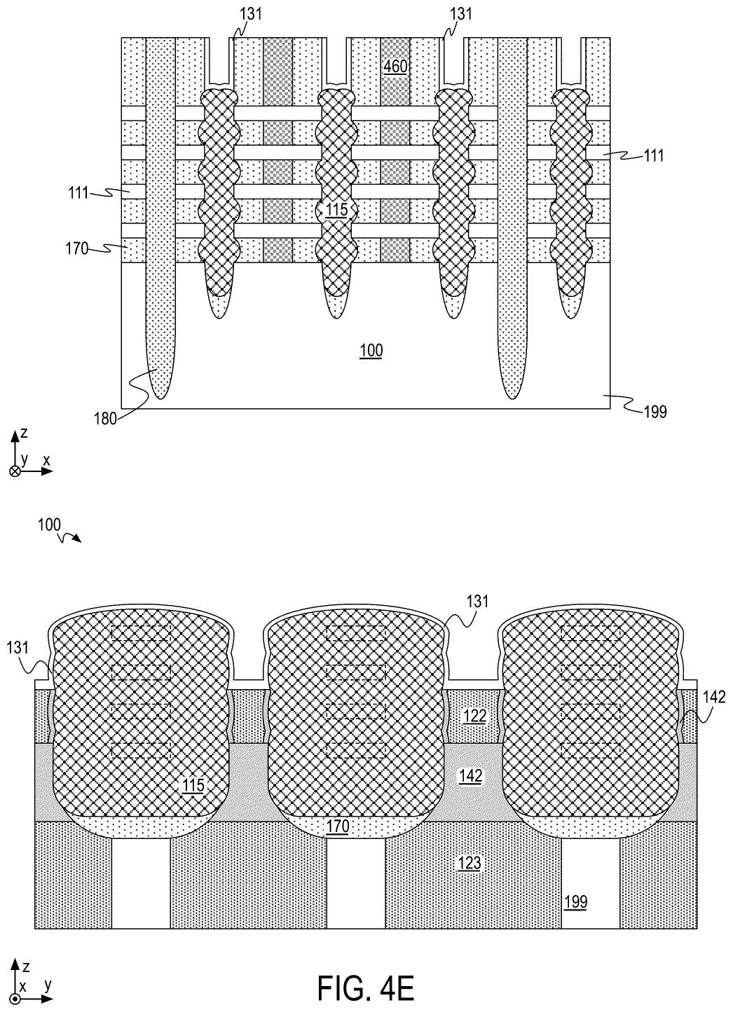

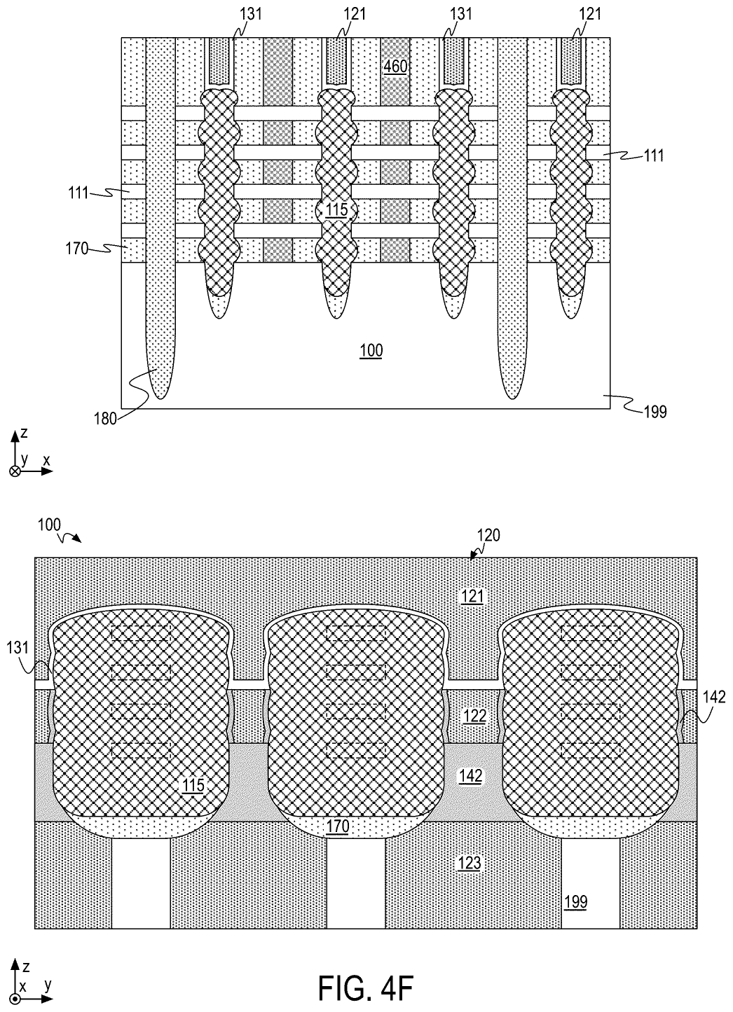

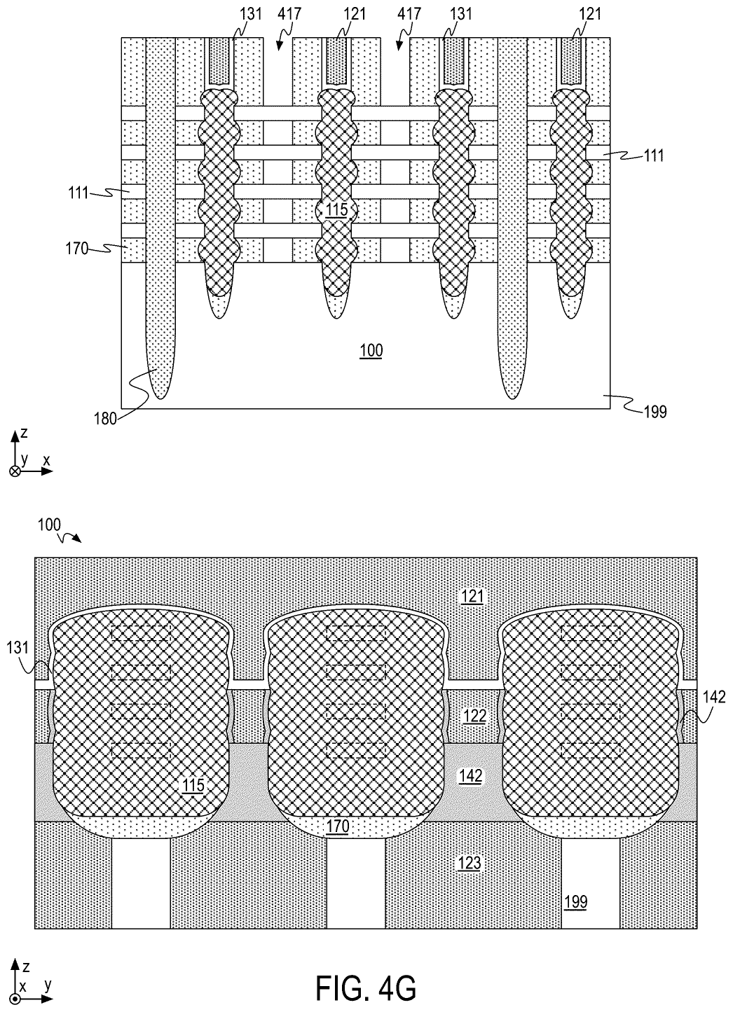

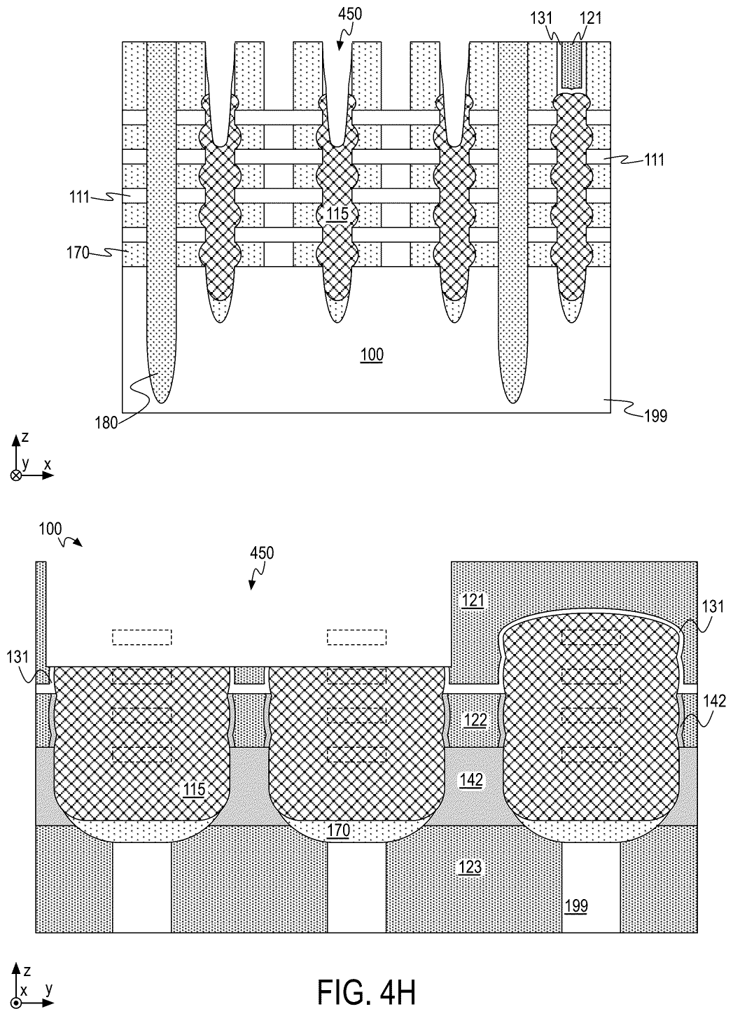

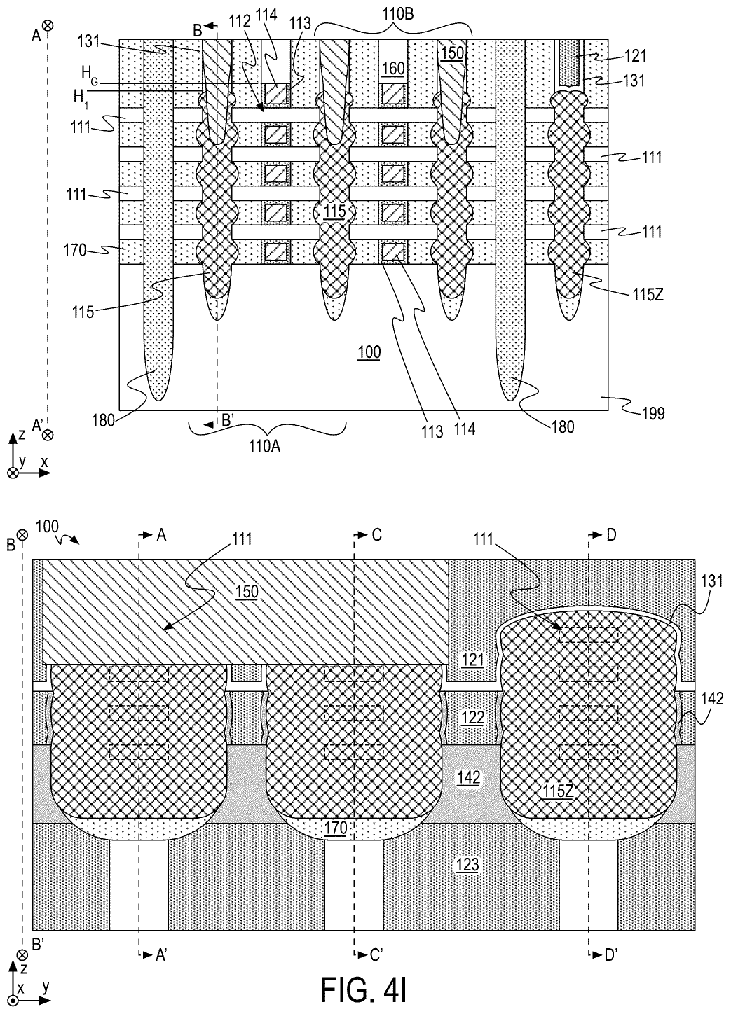

FIGS. 4A, 4B, 4C, 4D, 4E, 4F, 4G, 4H, and 4I illustrate cross-sectional profile views of IC device 100 having low-profile epitaxial structures 115 coupled to nanoribbons 111, at various stages of manufacture, in accordance with some embodiments. Orthogonal perspectives (e.g., both xz- and yz-viewing planes) are shown in each of FIGS. 4A-4I.

Returning to FIG. 3, methods 300 begin with receiving a substrate at operation 310. The substrate may be much as described previously herein (e.g., of substrate 199, at least at FIG. 1A). The substrate may include a stack of nanoribbons and an epitaxial structure on an end of the stack of nanoribbons. The epitaxial structure may have an initial height (e.g., as received) that exceeds, for example, an acceptable maximum height for one or more operations subsequent to receipt. For example, the epitaxial structure may have an excessively tall height that would interfere with a polishing operation (e.g., of a gate metal adjacent the epitaxial structure). In other examples, the epitaxial structure may have an excessively tall height that would correspond to an overly high inter-terminal capacitance.

FIG. 4A shows one or more stacks of nanoribbons 111 in or over substrate 199, and epitaxial structures 115 coupled to ends of nanoribbons 111 (e.g., following a receiving operation 310 of methods 300). Spacer structures 170 are on both sides of epitaxial structures 115, between epitaxial structures 115 and both isolation structures 180 and dummy gate structures 460. Heights H₁ (e.g., heights H_{1A}, H_{1B}) to top of epitaxial structures 115 are shown for reference, for example, prior to any recess etching. In some embodiments, a horizontal portion of dielectric layer 142 is already present, e.g., over isolation section 123. Some isolation structures 180 may be present as received or formed subsequently, for example, by deep isolation cuts or etches into or through nanoribbons and/or fins or the substrate.

Returning to FIG. 3, methods 300 continue with depositing a conformal layer over the epitaxial structure at operation 320. The conformal layer (e.g., between epitaxial structures and not-yet-formed dielectric materials) may protect epitaxial structures from subsequently formed dielectric materials (e.g., oxides). The conformal layer (e.g., between spacer structure sidewalls and not-yet-formed dielectric materials) may protect spacers from recess or contact etches of dielectric materials adjacent spacer structures. Advantageously, an etch selectivity exists between the conformal layer and the other dielectric materials. The conformal layer may be deposited by any suitable means and may be of, or include, any suitable material(s). In some embodiments, the conformal layer is deposited by chemical vapor deposition (CVD). In some embodiments, the conformal layer covers all exposed surfaces of the epitaxial structure, e.g., between spacer structures and over the substrate or any isolation (such as trench isolation) over the substrate. In some embodiments, the conformal layer covers exposed sidewall surfaces of adjacent spacer structures. In some embodiments, the conformal layer includes a horizontal portion between epitaxial structures, e.g., over the substrate or isolation over the substrate. In some embodiments, a horizontal nitride layer is already between epitaxial structures and over the substrate or isolation over the substrate.

In some embodiments, the conformal layer is of an electrically insulating material. In some embodiments, the conformal layer includes nitrogen (e.g., in a nitride, for example, of silicon). Other compositions may be employed. In some embodiments, the conformal layer has a substantially same atomic composition as the adjacent spacer structures.

FIG. 4B illustrates conformal layer 142 over epitaxial structures 115 (e.g., following a depositing operation 320 of methods 300). Layer 142 is over top surfaces of epitaxial structures 115 and over most of a height of epitaxial structures 115 in a gap between adjacent spacer structures 170. Layer 142 is over sidewall surfaces of adjacent spacer structures 170, for example, at a top of epitaxial structures 115.

Returning to FIG. 3, methods 300 continue by forming (e.g., depositing or growing) a dielectric material over the conformal layer and the epitaxial structure at operation 330. The dielectric material may provide electrical isolation between adjacent structures while providing a substrate or structure within which subsequent structures (e.g., contacts or other metallization structures) may be formed. In some embodiments, upper and lower portions of the dielectric material are deposited over the conformal layer and the epitaxial structure. In some such embodiments, a subsequent operation (e.g., an etch) will remove the upper portion and retain the lower portion. The dielectric material may be deposited may any suitable means and may be of, or include, any suitable material(s). In some embodiments, the dielectric material is deposited nonconformally by CVD. In some embodiments, the dielectric material is cured at an elevated temperature following deposition. In some such embodiments, the conformal layer protects the epitaxial structure from oxidation by the dielectric material.

In some embodiments, the dielectric material includes oxygen (e.g., in an oxide, for example, of silicon). Other compositions may be employed. In some embodiments, the dielectric material has a substantially same atomic composition as isolation structures, e.g., trenches, between adjacent stacks of nanoribbons.

FIG. 4C shows section 122 of dielectric material 120 over conformal layer 142 and epitaxial structures 115 (e.g., following a forming operation 330 of methods 300). Conformal layer 142 is over epitaxial structures 115, between epitaxial structures 115 and section 122 of material 120, and advantageously protects epitaxial structures 115 from section 122. Upper and lower portions 422A, 422B of section 122 and dielectric material 120 may subsequently be removed and retained, respectively.

Returning to FIG. 3, methods 300 continue at operation 340 with recessing the dielectric material, for example, by a recess etch. In many embodiments, the recessing removes an upper portion of the dielectric material. In many embodiments, the recessing retains a lower portion of the dielectric material. In some embodiments, a recess etch is somewhat selective to the epitaxial structure and/or the conformal layer. In some such embodiments, the dielectric material is recessed lower than the epitaxial structure and/or the conformal layer. In some embodiments, a recess etch is similar to a contact etch that exposes an epitaxial structure, but the recess etch is performed, e.g., prior to a dummy gate removal operation rather than after. The recessing may be by any suitable means. In some embodiments, a dry reactive ion etch (RIE), such as a deep RIE (DRIE), provides a high-aspect ratio etch of the dielectric material between spacer structures. The conformal layer advantageously protects structures, e.g., spacer structures, from such a high-energy recess etch. Such protection may help maintain the high aspect ratio of the etch, e.g., by preventing or minimizing lateral etching (widening) into the spacers.

In many embodiments, the recessing reduces a height of the epitaxial structure, for example, from a height as received to a lower, shorter height. In some such embodiments, the reduced height is lower than a gate height (e.g., of a dummy gate structure, an existing gate structure, or a subsequently formed gate structure). In some such embodiments, the reduced height is within a vertical nanoribbon pitch of a height of the top nanoribbon surface. In some such embodiments, the reduced height is within a nanoribbon thickness (e.g., the top nanoribbon thickness) of a height of the top nanoribbon surface. In some embodiments, the recessing causes more significant recessing in a middle of the etch than at edges of the epitaxial structure, and a height at a middle of the epitaxial structure may be lower than a height at an edge of the epitaxial structure (e.g., adjacent spacer material).

FIG. 4D illustrates low-profile epitaxial structures 115 and retained portions 422B of dielectric sections 122 between segments of conformal layer 142 and epitaxial structures 115 (e.g., following a recessing operation 340 of methods 300). For example, epitaxial structures 115 have a height H₁ much reduced from, e.g., FIGS. 4A-4C. In some embodiments, a difference between a reduced height H₁ of epitaxial structures 115 (e.g., following a recess etch) and height H₃ to a top surface of a top nanoribbon 111 is less than vertical pitch P_{NR}. In some such embodiments, the difference between a reduced height H₁ and height H₃ is less than thickness TNR of the top nanoribbon 111.

Returning to FIG. 3, methods 300 continue at operation 350 by depositing a second conformal layer over the epitaxial structure and the retained second portion. The second conformal layer may protect epitaxial structures from subsequently deposited dielectric materials (e.g., oxides) and during various operations prior to exposing for forming electrical contacts. The second conformal layer may be deposited much as the first conformal layer (at operation 320). The second conformal layer may be deposited may any suitable means and may be of, or include, any suitable material(s). In some embodiments, the second conformal layer is deposited by CVD. In some embodiments, the second conformal layer covers all exposed surfaces of the epitaxial structure, e.g., between spacer structures and over the substrate or any isolation (such as trench isolation) over the substrate. In some embodiments, the second conformal layer covers exposed sidewall surfaces of adjacent spacer structures. In some embodiments, the second conformal layer includes a horizontal portion between epitaxial structures, e.g., over the deposited dielectric material.

In some embodiments, the second conformal layer is of an electrically insulating material. In some embodiments, the second conformal layer includes nitrogen (e.g., in a nitride, for example, of silicon). Other compositions may be employed. In some embodiments, the second conformal layer has a substantially same atomic composition as the first conformal layer. In some embodiments, the second conformal layer has a substantially same atomic composition as the adjacent spacer structures.

FIG. 4E shows conformal layer 131 over epitaxial structures 115 (e.g., following a depositing operation 350 of methods 300). Layer 131 is over top surfaces of reduced-height epitaxial structures 115 and over an uppermost region of epitaxial structures 115 in a gap between adjacent spacer structures 170. Layer 131 is over retained portions of dielectric sections 122 around and between epitaxial structures 115. Layer 131 is over sidewall surfaces of adjacent spacer structures 170, for example, at a top of epitaxial structures 115.

Returning to FIG. 3, methods 300 continue with forming a third portion of the dielectric material over the second conformal layer and the epitaxial structure at operation 360. The dielectric material may again provide electrical isolation and a substrate or material within which subsequent structures may be formed. The dielectric material may be deposited may any suitable means and may be of, or include, any suitable material(s). In some embodiments, the dielectric material is deposited nonconformally by CVD. In some embodiments, the dielectric material is cured at an elevated temperature following deposition. In some such embodiments, the second conformal layer protects the epitaxial structure from oxidation by the dielectric material.

In some embodiments, the dielectric material includes oxygen (e.g., in an oxide). Other compositions may be employed. In some embodiments, the dielectric material has a substantially same atomic composition as the first and second portions of the dielectric material. In some embodiments, the dielectric material has a substantially same atomic composition as isolation structures, such as trenches.

FIG. 4F illustrates dielectric section 121 over conformal layer 131 over both epitaxial structures 115 and dielectric section(s) 122 (e.g., following a forming operation 360 of methods 300). Conformal layer 131 is over epitaxial structures 115, between epitaxial structures 115 and section 121 of material 120, between sections 121, 122 of material 120 and advantageously protects epitaxial structures 115 from section 121.

Returning to FIG. 3, methods 300 optionally continue at operation 370 with removing a dummy gate structure. In some embodiments, the received stack of nanoribbons extends through a dummy gate structure. In some such embodiments, the dummy gate structure is removed after a first recessing (e.g., etch) of the dielectric material is performed, but prior to a second recessing of the dielectric material (e.g., a contact etch). Performing a contact etch (e.g., second recessing of the dielectric material) and contact formation after removing a dummy gate structure may be preferred due to the high-temperature operations during gate processing (e.g., sacrificial or dummy gate removal and replacement) and the intolerance of contact metallization to high temperatures. However, the first recessing (e.g., recess etch) of the dielectric material may be necessary to facilitate subsequent processing prior to contact etch and formation. For example, epitaxial structure heights may need to be reduced (e.g., by a first recess etch) prior to CMP operations before dummy gate removal and replacement.

FIG. 4G shows reduced-height epitaxial structures 115 between spacer structures 170 and dummy gate structures 460 absent (e.g., following a removing operation 370 of methods 300). Openings 417 in spacer structures 170 adjacent nanoribbons 111 are available for subsequent formation of replacement gates.

Returning to FIG. 3, methods 300 continue at operation 380 by exposing the epitaxial structure by etching a second recess of the dielectric material, for example, a contact etch. A second recessing may be similar to a first recess (e.g., etch). In many embodiments, the second recessing of the dielectric material removes a portion (such as an upper portion) of the dielectric material over the epitaxial structure, e.g., at least some of the third portion formed over the second conformal layer. In many embodiments, the second recessing of the dielectric material removes a sector of the second conformal layer over the epitaxial structure. In some embodiments, the second recessing retains a lower portion of the dielectric material. In some embodiments, a second recessing etch is somewhat selective to the epitaxial structure and/or the conformal layer. In many embodiments, the dielectric material is recessed lower than the epitaxial structure.

FIG. 4H illustrates openings 450 between spacer structures 170 and over reduced-height epitaxial structures 115 (e.g., following an exposing and second recessing operation 380 of methods 300). Multiple epitaxial structures 115 are exposed, recessed down a centerline of epitaxial structures 115 between spacer structures 170, but recessed epitaxial structures 115 may have substantially the same heights (e.g., to a top or highest point) as non-recessed epitaxial structures 115. Conformal, intervening layer 131 is still over non-recessed epitaxial structure 115 and between non-recessed epitaxial structure 115 and dielectric section 121.

Methods 300 continue with forming a metal gate structure and a metal contact over the exposed epitaxial structure at operation 390. In some embodiments, following removing a dummy gate structure and a second recessing of epitaxial structures, metal contacts (e.g., metallization structures) are formed over the exposed epitaxial structure, for example, after a metal gate structure is formed, e.g., within a conformal layer of a gate dielectric. As discussed, the order of operations (e.g., dummy gate removal between first and second recess etches) may aid in managing a thermal budget of a manufacturing process.

FIG. 4I shows contacted and non-contacted epitaxial structures 115, 115Z in IC device 100 (e.g., following a forming operation 390 of methods 300). Device 100 in FIG. 4I is much as described at least at FIGS. 1A-1D. As previously described, most processing was the same or similar for epitaxial structures 115 (including epitaxial structures 115Z). The first recessing of the dielectric material (e.g., at operation 340) reduced the heights H₁ of epitaxial structures 115 (including epitaxial structures 115Z), e.g., to substantially same or similar heights H₁. Second conformal layer 131 was deposited over epitaxial structures 115 (including epitaxial structures 115Z). Upper dielectric section 121 was formed over epitaxial structures 115 (including epitaxial structures 115Z).

Notably, the etching the second recess of the dielectric material does not expose (non-contacted) epitaxial structures 115Z, and (non-contacted) epitaxial structures 115Z are not connected to a formed metal contact. Though not contacted, epitaxial structures 115Z have clearly been reduced in height by the first recessing.

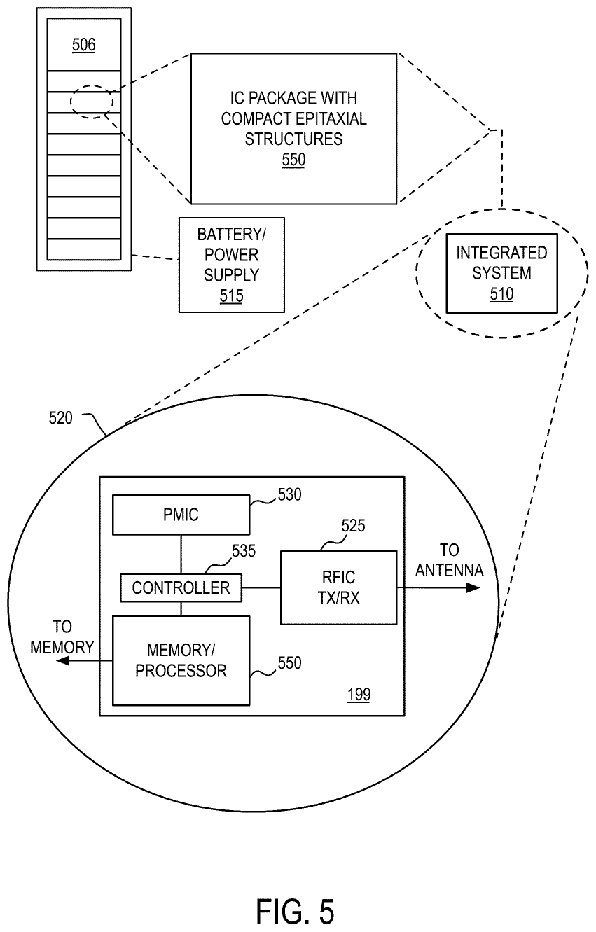

FIG. 5 illustrates a diagram of an example data server machine 506 employing an IC device having compact epitaxial structures, in accordance with some embodiments. Server machine 506 may be any commercial server, for example, including any number of high-performance computing platforms disposed within a rack and networked together for electronic data processing, which in the exemplary embodiment includes one or more devices 550 having compact epitaxial structures.

Also as shown, server machine 506 includes a battery and/or power supply 515 to provide power to devices 550, and to provide, in some embodiments, power delivery functions such as power regulation. Devices 550 may be deployed as part of a package-level integrated system 510. Integrated system 510 is further illustrated in the expanded view 520. In the exemplary embodiment, devices 550 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 550 is a microprocessor including a static RAM (SRAM) cache memory. As shown, device 550 may be an IC device having compact epitaxial structures, as discussed herein. Device 550 may be further coupled to (e.g., communicatively coupled to) a board, an interposer, or a substrate 199 along with, one or more of a power management IC (PMIC) 530, RF (wireless) IC (RFIC) 525 including a wideband RF (wireless) transmitter and/or receiver (TX/RX) (e.g., including a digital baseband and an analog front end module further includes a power amplifier on a transmit path and a low noise amplifier on a receive path), and a controller 535 thereof. In some embodiments, RFIC 525, PMIC 530, controller 535, and device 550 include compact epitaxial structures.

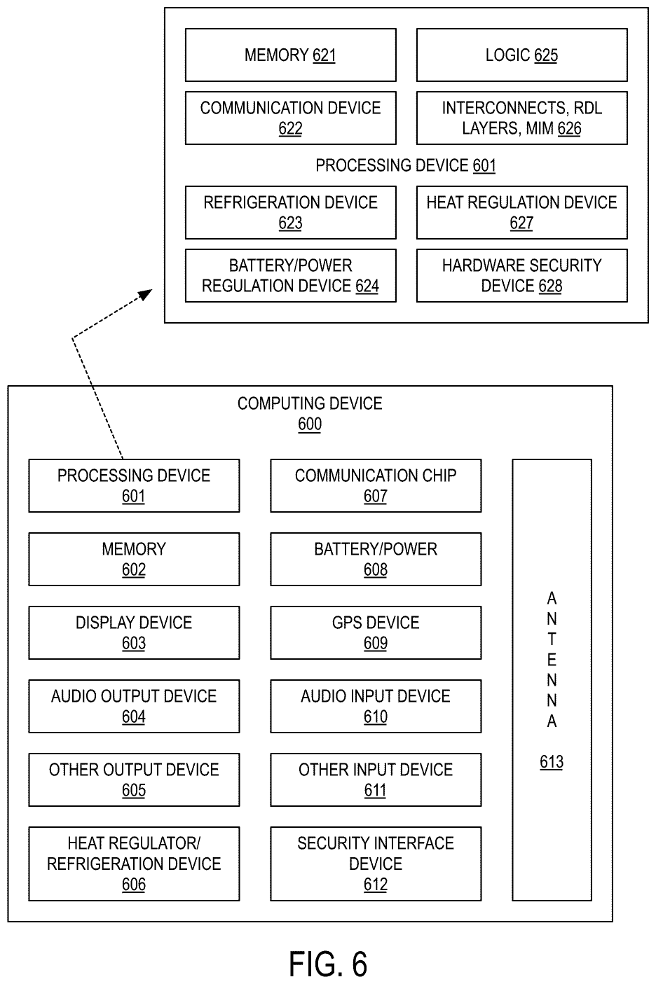

FIG. 6 is a block diagram of an example computing device 600, in accordance with some embodiments. For example, one or more components of computing device 600 may include any of the devices or structures discussed herein. A number of components are illustrated in FIG. 6 as being included in computing device 600, but any one or more of these components may be omitted or duplicated, as suitable for the application. In some embodiments, some or all of the components included in computing device 600 may be attached to one or more printed circuit boards (e.g., a motherboard). In some embodiments, various ones of these components may be fabricated onto a single system-on-a-chip (SoC) die. Additionally, in various embodiments, computing device 600 may not include one or more of the components illustrated in FIG. 6, but computing device 600 may include interface circuitry for coupling to the one or more components. For example, computing device 600 may not include a display device 603, but may include display device interface circuitry (e.g., a connector and driver circuitry) to which display device 603 may be coupled. In another set of examples, computing device 600 may not include an audio output device 604, other output device 605, global positioning system (GPS) device 609, audio input device 610, or other input device 611, but may include audio output device interface circuitry, other output device interface circuitry, GPS device interface circuitry, audio input device interface circuitry, audio input device interface circuitry, to which audio output device 604, other output device 605, GPS device 609, audio input device 610, or other input device 611 may be coupled.

Computing device 600 may include a processing device 601 (e.g., one or more processing devices). As used herein, the term “processing device” or “processor” indicates a device that processes electronic data from registers and/or memory to transform that electronic data into other electronic data that may be stored in registers and/or memory. Processing device 601 may include a memory 621, a communication device 622, a refrigeration device 623, a battery/power regulation device 624, logic 625, interconnects 626 (i.e., optionally including redistribution layers (RDL) or metal-insulator-metal (MIM) devices), a heat regulation device 627, and a hardware security device 628.

Processing device 601 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 600 may include a memory 602, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 602 includes memory that shares a die with processing device 601. This memory may be used as cache memory and may include embedded dynamic random-access memory (eDRAM) or spin transfer torque magnetic random-access memory (STT-MRAM).

Computing device 600 may include a heat regulation/refrigeration device 606. Heat regulation/refrigeration device 606 may maintain processing device 601 (and/or other components of computing device 600) at a predetermined low temperature during operation.

In some embodiments, computing device 600 may include a communication chip 607 (e.g., one or more communication chips). For example, the communication chip 607 may be configured for managing wireless communications for the transfer of data to and from computing device 600. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 607 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 607 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 607 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 607 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 607 may operate in accordance with other wireless protocols in other embodiments. Computing device 600 may include an antenna 613 to facilitate wireless communications and/or to receive other wireless communications (such as AM or FM radio transmissions).

In some embodiments, communication chip 607 may manage wired communications, such as electrical, optical, or any other suitable communication protocols (e.g., the Ethernet). As noted above, communication chip 607 may include multiple communication chips. For instance, a first communication chip 607 may be dedicated to shorter-range wireless communications such as Wi-Fi or Bluetooth, and a second communication chip 607 may be dedicated to longer-range wireless communications such as GPS, EDGE, GPRS, CDMA, WiMAX, LTE, EV-DO, or others. In some embodiments, a first communication chip 607 may be dedicated to wireless communications, and a second communication chip 607 may be dedicated to wired communications.

Computing device 600 may include battery/power circuitry 608. Battery/power circuitry 608 may include one or more energy storage devices (e.g., batteries or capacitors) and/or circuitry for coupling components of computing device 600 to an energy source separate from computing device 600 (e.g., AC line power).

Computing device 600 may include a display device 603 (or corresponding interface circuitry, as discussed above). Display device 603 may include any visual indicators, such as a heads-up display, a computer monitor, a projector, a touchscreen display, a liquid crystal display (LCD), a light-emitting diode display, or a flat panel display, for example.

Computing device 600 may include an audio output device 604 (or corresponding interface circuitry, as discussed above). Audio output device 604 may include any device that generates an audible indicator, such as speakers, headsets, or earbuds, for example.

Computing device 600 may include an audio input device 610 (or corresponding interface circuitry, as discussed above). Audio input device 610 may include any device that generates a signal representative of a sound, such as microphones, microphone arrays, or digital instruments (e.g., instruments having a musical instrument digital interface (MIDI) output).

Computing device 600 may include a GPS device 609 (or corresponding interface circuitry, as discussed above). GPS device 609 may be in communication with a satellite-based system and may receive a location of computing device 600, as known in the art.

Computing device 600 may include other output device 605 (or corresponding interface circuitry, as discussed above). Examples of the other output device 605 may include an audio codec, a video codec, a printer, a wired or wireless transmitter for providing information to other devices, or an additional storage device.

Computing device 600 may include other input device 611 (or corresponding interface circuitry, as discussed above). Examples of the other input device 611 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 600 may include a security interface device 612. Security interface device 612 may include any device that provides security measures for computing device 600 such as intrusion detection, biometric validation, security encode or decode, access list management, malware detection, or spyware detection.

Computing device 600, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-6. The subject matter may be applied to other deposition applications, as well as any appropriate manufacturing application, as will be understood to those skilled in the art.

The following examples pertain to further embodiments, and specifics in the examples may be used anywhere in one or more embodiments. [reserved for embodiments reflecting the claims]

In one or more first embodiments, an apparatus includes first and second doped semiconductor regions in a transistor structure, the first and second doped semiconductor regions coupled to a plurality of nanoribbons therebetween, a first section of a first dielectric material adjacent the first doped semiconductor region, wherein the first dielectric material includes oxygen, a second section of the first dielectric material under and adjacent the first section of the first dielectric material, and a first layer of a second dielectric material between the first and second sections of the first dielectric material and in contact with the first doped semiconductor region, wherein the second dielectric material includes nitrogen.

In one or more second embodiments, further to the first embodiments, the first layer contacts the first doped semiconductor region and the first section of the first dielectric material between the first section of the first dielectric material and the first doped semiconductor region.

In one or more third embodiments, further to the first or second embodiments, the apparatus also includes a second layer of a third dielectric material, wherein the third dielectric material includes nitrogen, and the second layer contacts the first doped semiconductor region between the second section of the first dielectric material and the first doped semiconductor region.

In one or more fourth embodiments, further to the first through third embodiments, the second layer of the third dielectric material is under and adjacent the second section of the first dielectric material, and the second layer of the third dielectric material is between the second section of the first dielectric material and a third section of the first dielectric material.

In one or more fifth embodiments, further to the first through fourth embodiments, a top of the first doped semiconductor region is at a first height, and the first layer of the second dielectric material between the first and second sections of the first dielectric material is at a second height more than a third of the first height and less than two thirds of the first height.

In one or more sixth embodiments, further to the first through fifth embodiments, a third height to a top surface of a top nanoribbon of the plurality of nanoribbons is within a vertical pitch to a first height at a top of the first doped semiconductor region, the vertical pitch equal to a distance between corresponding surfaces of adjacent first and second nanoribbons of the plurality of nanoribbons.

In one or more seventh embodiments, further to the first through sixth embodiments, the third height to the top surface of the top nanoribbon of the plurality of nanoribbons is within a thickness of the top nanoribbon to the first height at the top of the first doped semiconductor region.

In one or more eighth embodiments, further to the first through seventh embodiments, the apparatus also includes a plurality of metal structures, wherein a first metal structure is in contact with the first doped semiconductor region, and a second metal structure is in contact with the second doped semiconductor region, and a third doped semiconductor region adjacent the first doped semiconductor region, wherein the third doped semiconductor region is not in contact with any of the metal structures, and a first height at a top of the first doped semiconductor region is substantially equal to a fourth height at a top of the third doped semiconductor region.

In one or more ninth embodiments, an apparatus includes a plurality of epitaxial structures in an integrated circuit (IC) die, wherein a first epitaxial structure is on an end of a stack of nanoribbons in a transistor structure and is in contact with a metallization structure over the first epitaxial structure, a second epitaxial structure is adjacent the first epitaxial structure and not contacted by any metallization structure, the first epitaxial structure has a first height, and the second epitaxial structure has a second height substantially equal to the first height, a nitride layer in contact with both the first and second epitaxial structures, and first and second oxide regions adjacent and between the first and second epitaxial structures, the nitride layer between the first and second oxide regions.

In one or more tenth embodiments, further to the ninth embodiments, the nitride layer is a first nitride layer, also including a second nitride layer in contact with both the first and second epitaxial structures, wherein the second oxide region is between the first and second nitride layers.

In one or more eleventh embodiments, further to the ninth or tenth embodiments, the first nitride layer is in contact with the first and second oxide regions, the second nitride layer is in contact with the second oxide region, the first nitride layer is between the first oxide region and the first epitaxial structure and between the first oxide region and the second epitaxial structure, and the second oxide region is over the second nitride layer.

In one or more twelfth embodiments, further to the ninth through eleventh embodiments, the first oxide region includes a first atomic composition of at least twenty percent silicon and at least twenty percent oxygen, the second oxide region includes a second atomic composition of at least twenty percent silicon and at least twenty percent oxygen, the first nitride layer includes a third atomic composition of at least twenty percent silicon and at least twenty percent nitrogen, and the second nitride layer includes a fourth atomic composition of at least twenty percent silicon and at least twenty percent nitrogen.

In one or more thirteenth embodiments, further to the ninth through twelfth embodiments, the fourth atomic composition of the second nitride layer is substantially the same as the third atomic composition of the first nitride layer.

In one or more fourteenth embodiments, further to the ninth through thirteenth embodiments, the apparatus also includes a gate structure in the transistor structure, the gate structure including a gate dielectric around a gate metal and adjacent the nanoribbons, wherein a spacer structure is between the gate structure and the first epitaxial structure, the second nitride layer has a second composition, and the spacer structure has a third composition substantially the same as the second composition.

In one or more fifteenth embodiments, a method includes receiving a substrate including a stack of nanoribbons and an epitaxial structure on an end of the stack of nanoribbons, the epitaxial structure having a first height, depositing a first conformal layer over the epitaxial structure, forming first and second portions of a dielectric material over the first conformal layer and the epitaxial structure, recessing the dielectric material, wherein the recessing removes the first portion of the dielectric material, retains the second portion of the dielectric material, and reduces the epitaxial structure to a second height less than the first height, depositing a second conformal layer over the epitaxial structure and the retained second portion, and forming a third portion of the dielectric material over the second conformal layer and the epitaxial structure.

In one or more sixteenth embodiments, further to the fifteenth embodiments, the recessing the dielectric material reduces the epitaxial structure to the second height, a top surface of a top nanoribbon of the stack of nanoribbons is at a third height, and a difference between the second and third heights is less than a vertical pitch between corresponding surfaces of first and second nanoribbons in the stack of nanoribbons.

In one or more seventeenth embodiments, further to the fifteenth or sixteenth embodiments, the recessing the dielectric material reduces the epitaxial structure to the second height, the top surface of the top nanoribbon of the stack of nanoribbons is at the third height, and the difference between the second and third heights is less than a thickness of the top nanoribbon.

In one or more eighteenth embodiments, further to the fifteenth through seventeenth embodiments, the recessing the dielectric material is a first recessing, also including exposing the epitaxial structure by etching a second recess of the dielectric material, wherein the etching the second recess of the dielectric material removes a sector of the second conformal layer over the epitaxial structure and a fourth portion of the dielectric material over the epitaxial structure, the fourth portion including at least some of the third portion.

In one or more nineteenth embodiments, further to the fifteenth through eighteenth embodiments, the received stack of nanoribbons extends through a dummy gate structure, the method also including removing the dummy gate structure, wherein the first recessing of the dielectric material is performed prior to the removing the dummy gate structure, and the removing the dummy gate structure is performed prior to the etching the second recess of the dielectric material, and forming a metal gate structure and a metal contact over the exposed epitaxial structure.

In one or more twentieth embodiments, further to the fifteenth through nineteenth embodiments, the stack of nanoribbons is a first stack, the epitaxial structure is a first epitaxial structure, and the substrate further includes a second stack of nanoribbons and a second epitaxial structure, wherein the first recessing of the dielectric material reduces the second epitaxial structure to the second height, the second conformal layer is deposited over the second epitaxial structure, the third portion of the dielectric material is formed over the second epitaxial structure, the etching the second recess of the dielectric material does not expose the second epitaxial structure, and the second epitaxial structure is not connected to a formed metal contact.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
first and second doped semiconductor regions in a transistor structure, the first and second doped semiconductor regions coupled to a plurality of nanoribbons therebetween;
a first section of a first dielectric material adjacent the first doped semiconductor region, wherein the first dielectric material comprises oxygen;
a second section of the first dielectric material under and adjacent the first section of the first dielectric material; and
a first layer of a second dielectric material between the first and second sections of the first dielectric material and in contact with the first doped semiconductor region, wherein the second dielectric material comprises nitrogen.

2. The apparatus of claim 1, wherein the first layer contacts the first doped semiconductor region and the first section of the first dielectric material between the first section of the first dielectric material and the first doped semiconductor region.

3. The apparatus of claim 1, further comprising a second layer of a third dielectric material, wherein the third dielectric material comprises nitrogen, and the second layer contacts the first doped semiconductor region between the second section of the first dielectric material and the first doped semiconductor region.

4. The apparatus of claim 3, wherein the second layer of the third dielectric material is under and adjacent the second section of the first dielectric material, and the second layer of the third dielectric material is between the second section of the first dielectric material and a third section of the first dielectric material.

5. The apparatus of claim 1, wherein a top of the first doped semiconductor region is at a first height, and the first layer of the second dielectric material between the first and second sections of the first dielectric material is at a second height more than a third of the first height and less than two thirds of the first height.

6. The apparatus of claim 1, wherein a third height to a top surface of a top nanoribbon of the plurality of nanoribbons is within a vertical pitch to a first height at a top of the first doped semiconductor region, the vertical pitch equal to a distance between corresponding surfaces of adjacent first and second nanoribbons of the plurality of nanoribbons.

7. The apparatus of claim 6, wherein the third height to the top surface of the top nanoribbon of the plurality of nanoribbons is within a thickness of the top nanoribbon to the first height at the top of the first doped semiconductor region.

8. The apparatus of claim 1, further comprising:
a plurality of metal structures, wherein a first metal structure is in contact with the first doped semiconductor region, and a second metal structure is in contact with the second doped semiconductor region; and
a third doped semiconductor region adjacent the first doped semiconductor region, wherein the third doped semiconductor region is not in contact with any of the metal structures, and a first height at a top of the first doped semiconductor region is substantially equal to a fourth height at a top of the third doped semiconductor region.

9. An apparatus, comprising:
a plurality of epitaxial structures in an integrated circuit (IC) die, wherein a first epitaxial structure is on an end of a stack of nanoribbons in a transistor structure and is in contact with a metallization structure over the first epitaxial structure, a second epitaxial structure is adjacent the first epitaxial structure and not contacted by any metallization structure, the first epitaxial structure has a first height, and the second epitaxial structure has a second height substantially equal to the first height;
a nitride layer in contact with both the first and second epitaxial structures; and
first and second oxide regions adjacent and between the first and second epitaxial structures, the nitride layer between the first and second oxide regions.

10. The apparatus of claim 9, wherein the nitride layer is a first nitride layer, further comprising a second nitride layer in contact with both the first and second epitaxial structures, wherein the second oxide region is between the first and second nitride layers.

11. The apparatus of claim 10, wherein the first nitride layer is in contact with the first and second oxide regions, the second nitride layer is in contact with the second oxide region, the first nitride layer is between the first oxide region and the first epitaxial structure and between the first oxide region and the second epitaxial structure, and the second oxide region is over the second nitride layer.

12. The apparatus of claim 11, wherein the first oxide region comprises a first atomic composition of at least twenty percent silicon and at least twenty percent oxygen, the second oxide region comprises a second atomic composition of at least twenty percent silicon and at least twenty percent oxygen, the first nitride layer comprises a third atomic composition of at least twenty percent silicon and at least twenty percent nitrogen, and the second nitride layer comprises a fourth atomic composition of at least twenty percent silicon and at least twenty percent nitrogen.

13. The apparatus of claim 12, wherein the fourth atomic composition of the second nitride layer is substantially the same as the third atomic composition of the first nitride layer.

14. The apparatus of claim 12, further comprising a gate structure in the transistor structure, the gate structure comprising a gate dielectric around a gate metal and adjacent the nanoribbons, wherein a spacer structure is between the gate structure and the first epitaxial structure, the second nitride layer has a second composition, and the spacer structure has a third composition substantially the same as the second composition.

15. A method, comprising:
receiving a substrate comprising a stack of nanoribbons and an epitaxial structure on an end of the stack of nanoribbons, the epitaxial structure having a first height;
depositing a first conformal layer over the epitaxial structure;
forming first and second portions of a dielectric material over the first conformal layer and the epitaxial structure;
recessing the dielectric material, wherein the recessing removes the first portion of the dielectric material, retains the second portion of the dielectric material, and reduces the epitaxial structure to a second height less than the first height;
depositing a second conformal layer over the epitaxial structure and the retained second portion; and
forming a third portion of the dielectric material over the second conformal layer and the epitaxial structure.

16. The method of claim 15, wherein the recessing the dielectric material reduces the epitaxial structure to the second height, a top surface of a top nanoribbon of the stack of nanoribbons is at a third height, and a difference between the second and third heights is less than a vertical pitch between corresponding surfaces of first and second nanoribbons in the stack of nanoribbons.

17. The method of claim 16, wherein the recessing the dielectric material reduces the epitaxial structure to the second height, the top surface of the top nanoribbon of the stack of nanoribbons is at the third height, and the difference between the second and third heights is less than a thickness of the top nanoribbon.

18. The method of claim 15, wherein the recessing the dielectric material is a first recessing, further comprising exposing the epitaxial structure by etching a second recess of the dielectric material, wherein the etching the second recess of the dielectric material removes a sector of the second conformal layer over the epitaxial structure and a fourth portion of the dielectric material over the epitaxial structure, the fourth portion comprising at least some of the third portion.

19. The method of claim 18, wherein the received stack of nanoribbons extends through a dummy gate structure, the method further comprising:
removing the dummy gate structure, wherein the first recessing of the dielectric material is performed prior to the removing the dummy gate structure, and the removing the dummy gate structure is performed prior to the etching the second recess of the dielectric material; and
forming a metal gate structure and a metal contact over the exposed epitaxial structure.

20. The method of claim 19, wherein the stack of nanoribbons is a first stack, the epitaxial structure is a first epitaxial structure, and the substrate further comprises a second stack of nanoribbons and a second epitaxial structure, wherein:
the first recessing of the dielectric material reduces the second epitaxial structure to the second height;
the second conformal layer is deposited over the second epitaxial structure;
the third portion of the dielectric material is formed over the second epitaxial structure;
the etching the second recess of the dielectric material does not expose the second epitaxial structure; and
the second epitaxial structure is not connected to a formed metal contact.
